(19) United States
(12) Patent Application Publication
(10) Pub. No.: US 2006/0125079 A1
(43) Pub. Date: Jun. 15, 2006

(54) High density package interconnect wire bond strip line and method therefor

(76) Inventors: Chris Wyland, Livermore, CA (US); Wayne Nunn, Middletown, CA (US)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(21) Appl. No.: 10/537,666

(22) PCT Filed: Dec. 4, 2003
(86) PCT No.: PCT/IB03/05615

§ 371 Date: Jun. 6, 2005

Related U.S. Application Data
(60) Provisional application No. 60/432,530, filed on Dec. 10, 2002.

(51) Int. Cl. H01L 23/48

(52) U.S. Cl. 257/693

(57) ABSTRACT

In an example embodiment, an integrated circuit (105) is placed in a package (100), the package having signal pad connections, power connections, and ground connections. A lower strip line (110) is bonded by coupling a first ground connection (110a) of the IC (105) to a first package substrate ground connection (110b). After bonding the lower strip line, a plurality of wires (125) is bonded by a plurality of signal pads (125a) on a device die (105) being coupled to signal pad connections (125b) on the package substrate (100), the plurality of signal pads (125a) being in proximity to the first ground connection (110a) and the plurality of wires (125) maintained at a first predetermined distance from the lower strip line (110). After bonding the plurality of wires (125), an upper strip line (130) is bonded by coupling a second ground connection (130a) of the IC (105) with a second package substrate ground connection (130b), the upper strip line maintained at a second predetermined distance from the plurality of wires (125).

This application is related to concurrently filed application titled, “High Density Package Interconnect Power and Ground Strap and Method Therefor,” Attorney Docket Number US 02 0511P and is herein incorporated by reference in its entirety.

The invention relates to the field of integrated circuit packaging, and particularly to the control of the impedance of signal bond wires.

As integrated circuit technology improves to increase the density and complexity of devices that may be rendered in a given area of substrate, a significant challenge is posed to the packaging of these devices. In computer applications, for example, the width of the data bus has increased from 16, 32, 64, to 128 bits and beyond. During the movement of data in a system it is not uncommon for a bus to have simultaneously switching outputs (SSOs). The SSOs often result in the power and ground rails of the chip experiencing noise owing to the large transient currents present during the SSOs. If the noise is severe, the ground and power rails shift from their prescribed voltage causing unpredictable behavior in the chip.

In a BGA (Ball Grid Array) package, bond wires are often used to connect the device die to the ground on the package. In high pin count BGAs, a ground ring is commonly used. These bond wires are sometimes placed in close proximity to signal bond wires to control the impedance of signal bond wires by creating a coplanar waveguide structure.

U.S. Pat. Nos. 5,872,403 and 6,083,772 are directed to a structure and method of mounting a power semiconductor die on a substrate. They are directed in general, to power electronics and more specifically, to a low impedance heavy current conductor for a power device and method of manufacture.

U.S. Pat. No. 6,319,775 B1 relates to a method of making an integrated circuit package, and in particular to a process for attaching a conductive strap to an integrated circuit die and a lead frame. This patent and the previous two cited are incorporated by reference in their entirety.

The present invention is useful in controlling the impedance signal wires in a high count BGA package. By utilizing the bond wires of the package and placing ground planes above and below the bond wires, a strip line structure is created. The bond wires in the strip line are then sealed in the air between the ground planes by enclosing them in glue between the ends of the ground planes. The glue prevents the introduction of molding compound between the ground planes and signal wires so that the user may take advantage of the lower dielectric constant of air (εᵣ=1.00) compared to that of the molding compound (εᵣ=4.4).

In an example embodiment, an integrated circuit device (IC) having signal connections, power connections, and ground connections, is used to build a structure having interconnect wire bonds with a controlled impedance. The IC is placed in a package substrate, the package substrate having signal pad connections, power connections, and ground connections. A lower strip line is bonded by coupling a first ground connection of the IC to a first package substrate ground connection. After bonding the lower strip line, a plurality of wires is bonded by a plurality of signal pads on the device die being coupled to signal pad connections on the package substrate, with the plurality of signal pads being in proximity to the first ground connection and the plurality of wires maintained at a first predetermined distance from the lower strip line. After bonding the plurality of wires, an upper strip line is bonded by coupling a second ground connection of the IC with a second package substrate ground connection, the upper strip line maintained at a second predetermined distance from the plurality of wires.

Additional advantages and novel features will be set forth in the description which follows, and in part may become apparent to those skilled in the art upon examination of the following, or may be learned by practice of the invention.

The invention is explained in further details, by way of examples, and with reference to the accompanying drawings wherein:

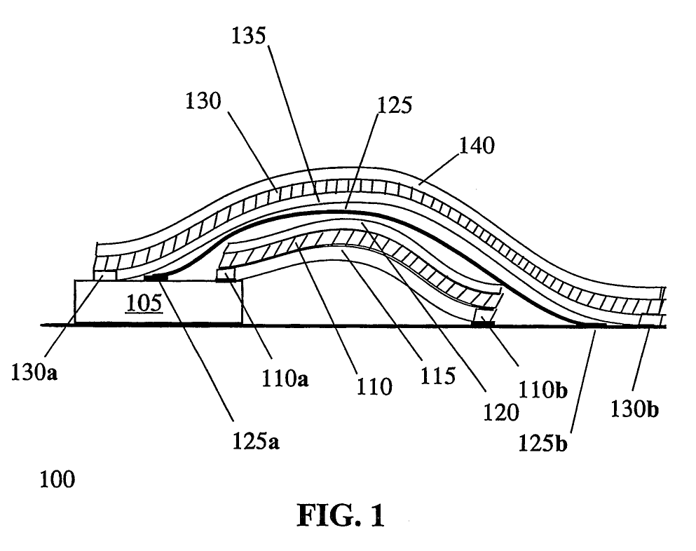

FIG. 1 is a side view of an embodiment according to the present invention; and

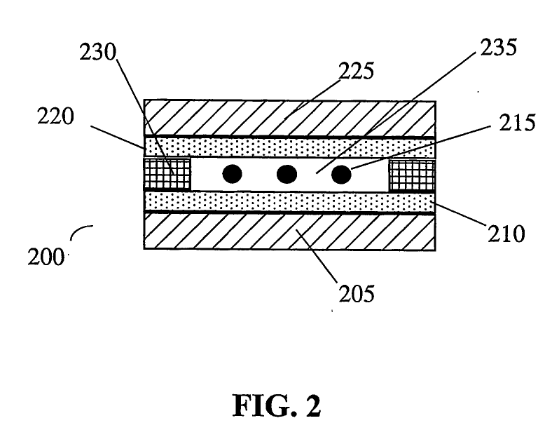

FIG. 2 is a cross-section of another embodiment of the present invention comprised of a composite of materials; and

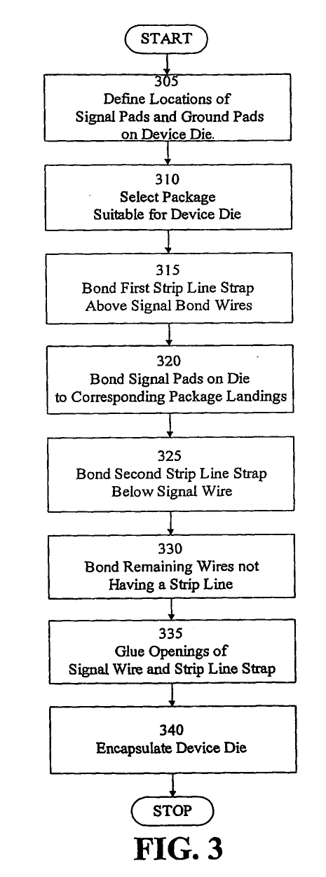

FIG. 3 outlines the steps in implementing the present invention in an example process; and

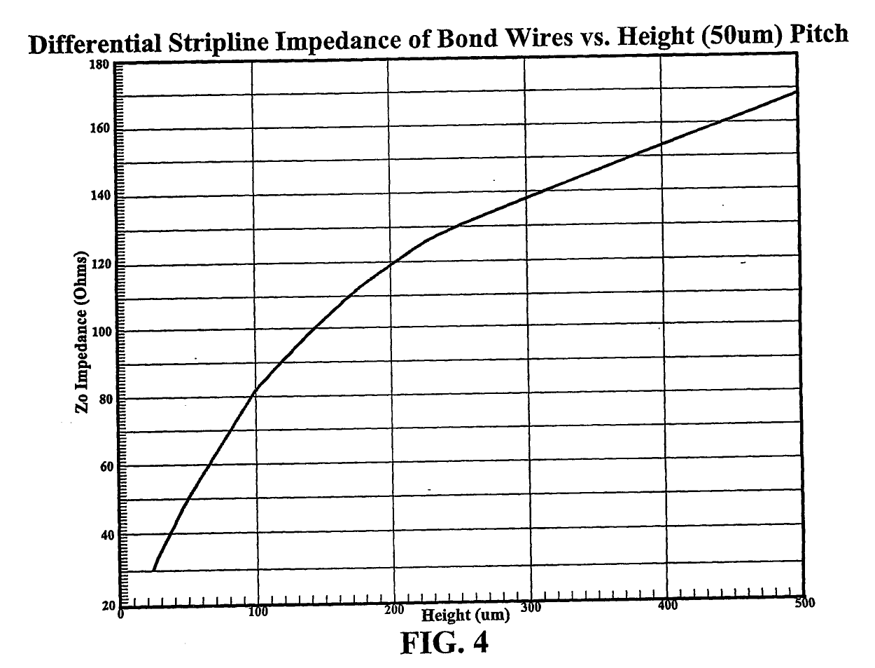

FIG. 4 is a plot of the impedance of a 25 μm bond wire at a 50 μm pitch vs. height from the strip line.

The present invention is advantageous for controlling the impedance of signal wires in a BGA package. By utilizing the bond wires of the package and placing ground planes above and below the bond wires, a strip line structure is created. The bond wires in the strip line are then sealed in the air between the ground planes by enclosing them in glue between the ends of the ground planes. The glue prevents the introduction of molding compound between the ground planes and signal wires so that the user may take advantage of the lower dielectric constant of air (εᵣ=1.00) compared to that of the molding compound (εᵣ=4.4).

Referring to FIG. 1, in an example embodiment according to the present invention, a low impedance power or ground connection is made between a device die and package in close proximity to signal wire bonds. This lessens the wire bonds' impedance. In an example package 100, a die 105 has been attached. Bond wire 125 connects a signal pad 125a on the die 105 to a signal package pin 125b. A first ground pad 110a in the vicinity of the signal pad 125a has a first strip line 110 connecting the ground pad 110a on the die 105 to a package ground 110b. The first strip line 110 may be comprised of copper or other suitable conductive material. At the ground pad 110a and the package ground 110b, the copper material may be clad with gold to improve solderability and provide a lower impedance connection. The package ground may be a ground ring surrounding the die to provide convenient connection of ground wires from the device die 105 to the package ground. To prevent short circuits, there may be an insulating material applied underneath 115 or on top of 120 the strip line 110. A second ground pad 130a in the vicinity of the signal pad 125a has a second strip line 130 connecting the ground pad 130a on the die 105 to a second package ground 130b. As with the first strip line 110, the second strip line 130 may have insulating material underneath 135 and insulating material top surface 140 of the second strip line. Although insulating material is useful in preventing short circuits, it is not required in some particular applications in which it can be assured that after bonding the various components according to the present invention, subsequent processing steps distort the bond wires and strip lines so that they contact one another. Some suitable insulating materials may be various non-conducting metallic oxides that adhere well to aluminum bond wires or to the copper strip lines. Insulating either suffices.

In an example embodiment, the user may be using aluminum bond wire. The outside surface of the bond wire may be oxidized to provide a non-conductive surface. In another example embodiment, a bond wire comprising copper, gold or other suitable metal may be used. However, a bonding layer, such as nickel may be applied. Upon the nickel, aluminum is electroplated then oxidized. Other coatings may be a variety of plastics such as polyimide, polyamide, epoxy, thermoplastics, etc. For reasons of conserving space, the metal oxides are the thinnest.

The above embodiment may be applicable to either ceramic or encapsulated BGA packages. For a ceramic BGA, the spacing between the signal bond wire and the two strip lines would be occupied by air. In a molded BGA, the mold compound would flow in between the spaces. Consequently, the dielectric constant for the configuration of FIG. 1 would be higher for a molded package versus a ceramic package.

To address the increase in the dielectric constant for the configuration of FIG. 1 for the present invention implemented in a molded package, areas in which strip lines are used, may be closed off with glue. The glue prevents the movement of any molding compound into any air space created by the signal bond wire and the first and second strip lines. Referring to FIG. 2, in another example embodiment according to the present invention, a strip line arrangement 200 has a lower strip line 205 having an insulating layer 210 applied thereon and an upper strip line 225 also having an insulating layer 220 applied thereon. An air space 235 separates the lower strip line 205 and the upper strip line 225. Bond wires 215 occupy the air space 235. Glue plugs 230 protect the air space 235. The glue prevents the introduction of molding compound between the ground planes and signal wires so that the user may take advantage of the lower dielectric constant of air (εᵣ=1.00) compared to that (εᵣ=4.4) of the molding compound. Having the lower dielectric constant enables faster signal propagation. In an example embodiment, using packaging materials with a minimum porosity, and with appropriate manufacturing equipment, it is possible to construct and maintain an interior vacuum under the strip line region. In another example embodiment, a partial vacuum can be maintained. The maintaining of even a partial vacuum provides a reduction in the dielectric constant.

Although not required, some advance planning of placing ground pads on the device and package in relation to signal pads may assist the user in implementing the strip lines according to the present invention. Referring now to FIG. 3, in an example device, a series of steps 300 may be used. The user defines locations of signal pads and ground pads on the device die at 305. A suitable package is selected for the device die at 310. A first strip line is bonded to a ground pad and package landing at 315. The signal pads on die are bonded to corresponding package landings at 320. A second strip line is bonded below the signal bond wire at 325 to construct an arrangement as depicted in FIGS. 1 and 2. If no grounding pad is exactly above and below the signal pad, grounding pads as close as practicable may be used instead. Remaining bond wires not having a strip line are then bonded at 330. If using a molded package, the openings of the signal wire and strip line straps are sealed with glue at 335 so that the air dielectric may be maintained. Bonding of remaining wires takes place at 340 prior to encapsulation of the device die at 340.

In another example embodiment according to the present invention, the impedance of bond wires is plotted with respect to the bond wires' distance from the strip line. The wires are 25 μm in diameter bonded with a 50 μm pitch. Referring now to FIG. 4, the plot indicates a range of impedance values that may be obtained by building a strip line to a particular distance from the bond wires. For example, at a height of 25 μm the characteristic impedance Zₒ is about 30 ohms. At another height of about 200 μm the characteristic impedance is about 120 ohms. For commonly used impedance values of about 50, 75, and 100 ohms, the heights (estimated from the plot) are about 50, 87, and 142 μm, respectively. At a height of 500 μm, the characteristic impedance of the bond wires is about 170 ohms. From this distance, the strip line has a negligible effect, as though no strip line were present.

While the present invention has been described with reference to several particular example embodiments, those skilled in the art will recognize that many changes may be made thereto without departing from the spirit and scope of the present invention, which is set forth in the following claims.

1. In an integrated circuit device (IC) having signal connections, power connections, and ground connections, the integrated circuit having been placed in a package substrate, the package substrate having signal pad connections, power connections, and ground connections, a method for building a structure having interconnect wire bonds having controlled impedance, the method comprising: bonding a lower strip line coupling a first ground connection of the IC to a first package substrate ground connection; bonding with a plurality of wires, a plurality of signal pads on a device die, coupling the plurality of signal pads to signal pad connections on the package substrate, the plurality of signal pads in proximity to the first ground connection and the plurality of wires maintained at a first predetermined distance from the lower strip line; and bonding an upper strip line coupling a second ground connection of the IC with a second package substrate ground connection, the upper strip line maintained at a second predetermined distance from the plurality of wires.

2. The method of claim 1 wherein the method further comprises: sealing openings in the upper strip line and the lower strip line with a dielectric material, thereby trapping air in the structure.

3. The method of claim 2 wherein the dielectric material is a glue.

4. A strip line structure controlling impedance of bond wires in an integrated circuit device (IC) placed in a package, the strip line structure comprising: a lower strip line coupling a first ground connection in the IC with a first ground connection in the package; an upper strip line coupling a second ground connection on the IC with a second ground connection in the package, the lower strip line and upper strip line being a predetermined distance apart from one another, forming a space accommodating a plurality of bond wires whose wire diameters are less than the predetermined distance, the bond wires not in electrical contact with the upper strip line and the lower strip line, the bond wires coupling a signal pin on the IC with a signal connection in the package.

5. The strip line structure of claim 4 wherein, the upper strip line and the lower strip line are glued together, hermetically sealing a space accommodating the plurality of bond wires.

6. The strip line structure of claim 5 wherein the space contains a dielectric selected from at least one of the following: vacuum, partial vacuum, nitrogen, oxygen, argon, xenon, neon, aerogels, and foams.

7. The strip line structure of claim 4 wherein the upper strip line and the lower strip line have an insulating material deposited on a side in proximity with the plurality of bond wires, respectively.

8. The strip line structure of claim 7 wherein the insulating material is selected from at least one of the following: polyimide, polyamide, soldermask, PTFE, TEFLON, and Kapton.

9. The strip line structure of claim 4, wherein the plurality of bond wires are covered with an insulating coating selected from at least one of the following: aluminum oxide, epoxy, thermoplastic, polyimide, and polyamide.

10. The strip line structure of claim 4 wherein the upper strip line and the lower strip line are comprised of copper.

11. The strip line structure of claim 4 wherein the upper strip line and the lower strip line are comprised of gold.

12. The strip line structure of claim 4 wherein the upper strip line and the lower strip line are comprised of silver.

13. The strip line structure of claim 4 wherein the upper strip line and the lower strip line are comprised of aluminum.

14. The strip line structure of claim 4 wherein the upper strip line and the lower strip line are comprised of a highly conductive material selected from: copper, gold, silver, aluminum and an alloy thereof.
